(19) United States
(12) Patent Application Publication
(10) Pub. No.: US 2012/0292304 A1
(43) Pub. Date: Nov. 22, 2012

(54) PORTABLE ELECTRONIC DEVICE CASE WITH ACTIVE THERMAL PROTECTION

(75) Inventors: Joshua D. Burchard, Somerville, MA (US); Michael J. Forte, Poughkeepsie, NY (US); Zamir G. Gonzalez, Poughkeepsie, NY (US); Jenny S. Li, Danbury, CT (US)

(73) Assignee: INTERNATIONAL BUSINESS MACHINES CORPORATION, Armonk, NY (US)

(21) Appl. No.: 13/108,574

(22) Filed: May 16, 2011

(51) Int. Cl. H05K 7/20; H05B 1/02; F28F 13/00

(52) U.S. Cl. 219/386; 165/80.2; 165/135; 219/494

(57) ABSTRACT

A device case for a portable electronic device is provided and includes mechanical protection for the device, an active thermal element incorporated within the mechanical protection and a controller to control an operation of the active thermal element, the controller being configured to limit power consumption of the active thermal element and to maintain a predefined internal device temperature.

### BACKGROUND

The present invention relates to a device case and, more particularly, to a portable electronic device case with active thermal protection.

Increasing numbers of people are purchasing portable electronic devices for personal or business use every day. These devices are being used in many different environments, including environments where the device might need to operate outside its normal operating temperature range. When a device is used outside its normal operating temperature range, the device might behave unpredictably or unreliably. For example, a portable music player left in a cold vehicle on a cold day, might not respond or might respond slowly to user attempts to use the device. Such behavior would be abnormal and lead to decreased reliability.

### SUMMARY

According to an aspect of the present invention, a device case for a portable electronic device is provided and includes mechanical protection for the device, an active thermal element incorporated within the mechanical protection and a controller to control an operation of the active thermal element, the controller being configured to limit power consumption of the active thermal element and to maintain a predefined internal device temperature.

According to another aspect of the present invention, a device case is provided and includes a thermal energy spreader disposed about or proximate to a component of a device, a temperature sensing element to sense a temperature of an environment about or proximate to the device and to issue a signal reflective thereof, a thermal element coupled to the temperature sensing element and disposed to selectively change the temperature of the environment about or proximate to the device in accordance with the signal and a layer to provide thermal insulation and impact protection disposed about the thermal energy spreader and the thermal element.

According to another aspect of the present invention, a device case for a device having computing capability is provided and includes a thermal energy spreader disposed about or proximate to a component of a device, a temperature sensing element to sense a temperature of an environment about or proximate to the device and to issue a signal reflective thereof, a thermal element coupled to the temperature sensing element and disposed to selectively change the temperature of the environment about or proximate to the device, a layer to provide thermal insulation and impact protection disposed about the thermal energy spreader and the thermal element and a connector to operably couple the device, the temperature sensing element and the thermal element, the thermal element being operable by the device in accordance with the signal.

According to another aspect of the present invention, a device case is provided and includes a thermal energy spreader disposed about or proximate to a component of a device, a temperature sensing element to sense a temperature of an environment about or proximate to the device and to issue a signal reflective thereof, a thermal element coupled to the temperature sensing element and disposed to selectively change the temperature of the environment about or proximate to the device, a layer to provide thermal insulation and impact protection disposed about the thermal energy spreader and the thermal element and a controller operably coupled to the temperature sensing element and the thermal element to control the thermal element in accordance with the signal.

According to yet another aspect of the invention, a method of operating a device case providing active thermal protection is provided and includes receiving user input at a device, determining whether to power a thermal element in an event the thermal element is not powered by sensing a temperature of an environment about the device, issuing a signal reflective thereof and activating the thermal element in an event the temperature is below a predefined limit and power is available and responding to the user input.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is an axial view of a device case;

FIG. 2 is a schematic diagram of a thermal element of the device case of FIG. 1;

FIG. 3 is a schematic diagram of control elements; and

FIG. 4 is a flow diagram illustrating an operation of a device case.

### DETAILED DESCRIPTION

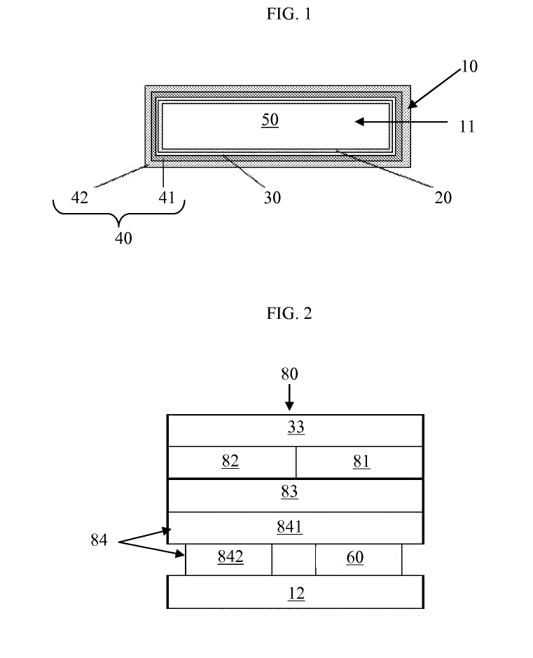

With reference now to FIGS. 1-3, a device case 10 is provided for use with a device 11, such as a personal digital assistant (PDA), a portable personal computer, a cell phone or any other similar portable device for computing or communication. The device 11 may include one or more components 12 that are operationally sensitive to high or low temperature environments. As an example, the components 12 include a liquid crystal touch screen that is slow to respond or non-responsive to touch in cold environments.

The device case 10 includes a thermal energy spreader 20, an active thermal element (“thermal element”) 30 and a layer 40, which is disposed about the thermal energy spreader 20 and the thermal element 30 to provide thermal insulation and mechanical, electro-magnetic, thermal and impact protection for the device 11 and/or a user thereof. The thermal energy spreader 20 may be a thin material, such as solid metal, metal mesh, thermally conductive silicone coated fabrics or a combination of materials, which distributes heat and prevents electro-magnetic interference. In an embodiment, the thermal energy spreader 20 is formed of a thermally conductive material, such as a metal or a metal alloy, and may be disposed about or proximate to the device 11. In particular, the thermal energy spreader 20 is provided about or proximate to the component 12 of the device 11, which, as noted above, may be sensitive to high or low temperature environments. The thermal element 30 is disposed to selectively change a temperature of the environment about or proximate to the device 11 or, more particularly, the component 12 in accordance with the temperature about or proximate to the device 11.

Because cycling electricity through a conductor, such as the thermal element 30 creates an electro-magnetic field, the field must be controlled. In an embodiment, control of the field is provided by the thermal energy spreader 20. Here, when designing the device case 10, a maximum amount of power to be provided to the thermal element 30 is considered with respect to the intensity of the electro-magnetic interference created and a type of the device 11. Additionally, consideration is given to a location of the thermal energy spreader 20 so as to not block radio waves or other transmission signals that must be emitted from or received by the device 11 for normal operation.

The device case 10 may further include a flap 50 by which a user interface of the device 11, such as the component 12 (see FIG. 2), is accessible to the user. The flap 50 is hinged with at least the thermal element 30 running in and out of the flap 50 by way of the hinge.

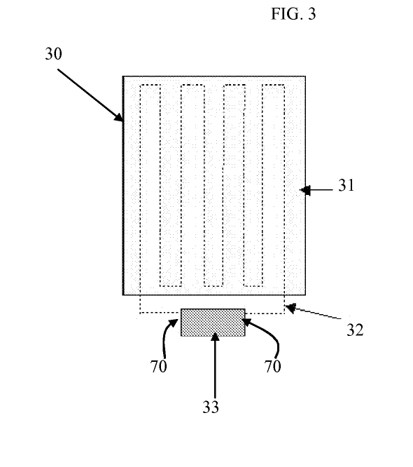

In accordance with embodiments, the thermal element 30 may be provided as a thermal layer having three separate layers including a thermal backing layer 31, a thermal conductor 32 and the thermal energy spreader 20. The thermal backing layer 31 may be a thin cloth, rubber or metal backing and provides protection and a mounting surface for the subsequent layers. The thermal conductor 32 is adhered to the thermal backing layer 31 and may be a patterned thermal conductor including a thin wire (i.e., copper) or advanced carbon fiber (i.e., nanotubes). Leads extend from the thermal conductor to connect with a control mechanism 33. In particular, the thermal conductor 32 may include an electrically resistive element that generates heat in the presence of a current applied thereto or a thermoelectric material that also generates heat in the presence of a current applied thereto. In particular, the thermal conductor 32 may be formed as a layer of material that is capable of exhibiting the Peltier effect. As shown in FIG. 3, the thermal conductor 32 of the thermal element 30 may be coupled to the control mechanism 33 such that, if it is determined that the device 11 or the component 12 is excessively hot or cold, the thermal element 30 can be activated as a cooling element or a heating element by the control mechanism 33 to apply a cooling or a heating effect.

The layer 40 includes an insulating layer 41 and a protective layer 42 adhered to one another. The insulating layer 41 is formed of thermally insulating material, such as a thin foam, silicon coated fabrics or other insulating materials, that may also be electrically non-conductive. The insulating layer 41 is disposed about the thermal element 30, in particular, or about the device 11 as a whole. In this way, a user of the device 11 does not risk thermal injury from the thermal element 30 when holding the device 11. The protective layer 42 conforms to the shape of and generally surrounds the device 11. The protective layer 42 is formed of soft, hard, compliant or elastic rubber or plastic material that can protect the device 11 from impacts, such as those caused by the user dropping the device 11 or accidentally banging the device 11 into another object.

As shown in FIG. 1, the device case 10 has an elongate cross-sectional shape that is similar to that of, for example, a cell phone or a PDA without being substantially larger than the cell phone or PDA. As such, the device 11 and the device case 10 can be handheld or, when not in use, contained within a pocket of a user's clothing or a carrying case.

With reference to FIG. 2, the device case 10 or the device 11 may further include a temperature sensing element 60, such as a thermocouple, which is disposed about, proximate or in contact with the device 11 or the component 12 or an interior of the device 11. As such, the temperature sensing element 60 is configured to sense a temperature of an environment about or proximate to the device 11 or the component 12. In some cases, the temperature sensing element 60 may be configured to directly sense a temperature of the device 11 or the component 12. In addition, the temperature sensing element 60 is configured to generate and issue a signal that is reflective of the sensed temperature. Where the device case 10 or the device 11 includes the temperature sensing element 60, the temperature sensing element 60 and the thermal element 30 may be operably coupled to one another whereby the thermal element 30 selectively changes the temperature of the environment about or proximate to the device 11 or the component 12.

The device 11 may have computing capability (as would be expected for, e.g., a PDA). In this case, the control mechanism 33, for example, may be a component of the device 11 and may be coupled to the central processing unit of the device 11. Here, the device 10 may further include a connector 70 (see FIG. 3) to operably couple the device 11, the temperature sensing element 60 and the thermal element 30 to one another. The thermal element 30 is thus operable by the control mechanism 33 in accordance with the signal provided by the temperature sensing element 60.

With reference to FIG. 2, in an alternative embodiment, the control mechanism 33 is operably coupled to the thermal element 30 and is included within a controller 80 as a component of the device case 10 or the device 11. In either case, the controller 80 includes or is coupled to the temperature sensing element 60 and is coupled to the thermal element 30 to thereby control the thermal element 30 in accordance with the signal issued by the temperature sensing element 60. The controller 80 may further include or be coupled to a power source 81 and a data interface 82.

The power source 81 serves to provide power at least to the thermal element 30 and may be provided as an external current (when the device 11 is being charged), a battery or the battery of the device 11. As a general matter, the power source 81 maybe provided as any array of power configurations depending on circuitry used to design the control mechanism 33. For example, the thermal element 30 could be powered using standard USB bus power. Higher voltage power sources could be used, however, in such cases attention must be given to prevent overheating the thermal element 30. The power source 81 may use alternating current (AC) or, more likely, direct current (DC). In accordance with embodiments, an amount of power provided to the thermal element 30 is controllable by the control mechanism 33 and may be held constant, regulated or changed by the control mechanism 33.

Because the power provided to the thermal element 30 is regulated, the thermal element 30 can further be controlled and power regulated with consideration given to remaining battery life of the device 11 and thermal protection requirements. For example, if operating the thermal element 30 would drain completely or drain the power source 81 below a predetermined threshold, the thermal element 30 can be disabled or minimal power only can be provided.

The controller 80 further includes a processing unit 83 to control an operation of the control mechanism 33, a storage medium 84, the temperature sensing unit 60 and the component 12 of the device 11 (i.e., the user interface). The storage medium 84 may be segmented into a first storage unit 841 for read/write memory and a second storage unit 842 for read only memory and has executable instructions stored thereon. When executed, the executable instructions cause the processing unit 83 to control the operation of the control mechanism 33 and may additionally cause the processing unit 83 to control an operation of the temperature sensing element 60 as well.

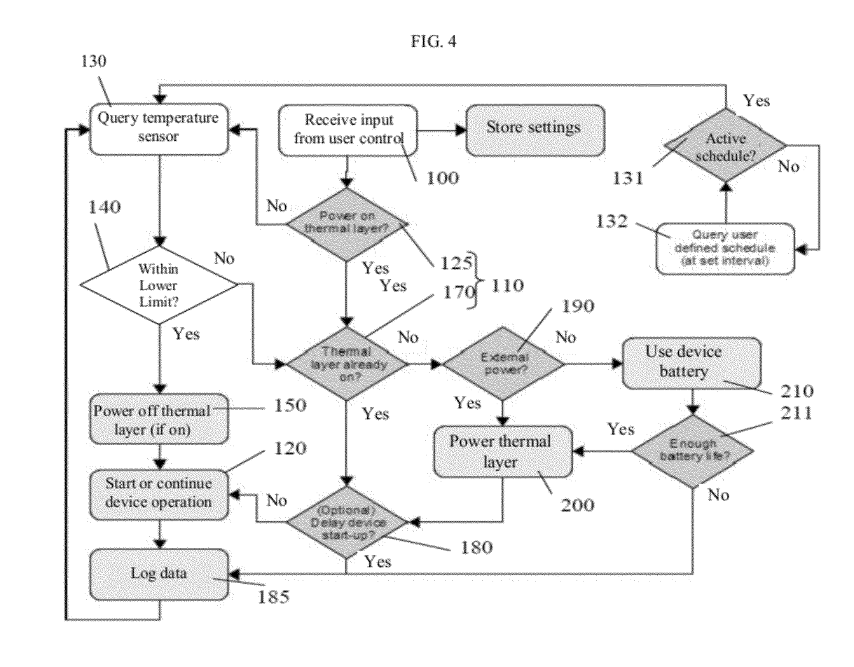

In accordance with further aspects of the invention with reference to FIG. 4, a method of operating the device case 10 for providing the device 11 with active thermal protection is provided. The method includes at operation 100 receiving user input for, e.g., starting the device 11, at the device 11 by way of the component 12 (i.e., where the component 12 is a user interface of the device 11). The method further includes at operation 110 determining whether to power on/off the thermal element 30 in an event the thermal element 30 is not powered and, at operation 120, responding to the user input by, e.g., starting the device 11 or continuing operation of the device 11.

More particularly, in response to the user input received at operation 100, the method includes determining whether the thermal element 30 should be powered at operation 125. If operation 125 indicates that the thermal element 30 should not be powered, control proceeds to operation 130 at which the temperature sensing element 60 is queried immediately or at a set interval. The set interval may be activated in accordance with operations 131, 132 during which it is determined whether an active schedule exists and, if not, a user defined schedule is queried. Once the temperature sensing element 60 is queried and issues a signal reflective of the sensed temperature, it is determined at operation 140 whether the temperature is within a lower limit. If the temperature is within the lower limit, the thermal element 30 remains not powered (or is turned off) at operation 150 and control proceeds to operation 120 at which the device 11 responds to the user input as set forth above.

If the temperature is not within the lower limit, as determined at operation 140, or if the thermal element 30 is determined to have been powered on at operation 125, it is re-determined at operation 170 whether the thermal element is already on and, if so, control proceeds to operation 180 where it is determined whether a delay needs to be conducted. If no delay is necessary, control proceeds to operation 120 at which the device responds to the user input. If the delay is necessary, the delay is conducted and control proceeds to operation 185 where log data of, for example, first storage unit 841 is updated. Control then proceeds to operation 130 at which the temperature sensing element 60 is queried immediately or at a set interval where the set interval is activated in accordance with operations 131, 132.

If it is re-determined at operation 170 that the thermal element 30 is not already on, control proceeds to operation 190 where it is determined whether external power (i.e., a charging device) is available. If the external power is available, control proceeds to operation 200 where the thermal element 30 is powered on and, then, operation 180 where it is determined whether the above-mentioned delay needs to be conducted. If, at operation 190, it is determined that external power is not available, control proceeds to operations 210, 211 during which it is determined whether a battery of either the device case 10 or the device 11 is to be used to power the thermal element 30 based on, for example, an amount of remaining available power and a type of computing tasks requiring power currently being queued. If the battery of either the device case 10 or the device 11 can be used to power the thermal element 30, control proceeds to operation 200 and the thermal element 30 is powered on. If the battery cannot be used, proceeds to operation 185 where log data of, for example, first storage unit 841 is updated. Control then proceeds to operation 130 at which the temperature sensing element 60 is queried immediately or at a set interval where the set interval is activated in accordance with operations 131, 132.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. A device case for a portable electronic device, comprising:
mechanical protection for the device;
an active thermal element incorporated within the mechanical protection; and
a controller to control an operation of the active thermal element, the controller being configured to limit power consumption of the active thermal element and to maintain a predefined internal device temperature.

2. The device case according to claim 1, wherein the mechanical protection comprises a protection layer and an insulation layer.

3. The device case according to claim 1, further comprising a thermal energy spreader operably interposed between the device and the active thermal element.

4. The device case according to claim 1, wherein the active thermal element comprises a thermal conductor.

5. A device case, comprising:
a thermal energy spreader disposed about or proximate to a component of a device;
a temperature sensing element to sense a temperature of an environment about or proximate to the device and to issue a signal reflective thereof;
a thermal element coupled to the temperature sensing element and disposed to selectively change the temperature of the environment about or proximate to the device in accordance with the signal; and
a layer to provide thermal insulation and impact protection disposed about the thermal energy spreader and the thermal element.

6. The device case according to claim 5, further comprising a flap by which a user interface of the device is accessible.

7. The device case according to claim 5, wherein the thermal element comprises an electrically resistive material.

8. The device case according to claim 5, wherein the thermal element comprises a thermoelectric material.

9. A device case for a device having computing capability, comprising:
a thermal energy spreader disposed about or proximate to a component of a device;
a temperature sensing element to sense a temperature of an environment about or proximate to the device and to issue a signal reflective thereof;
a thermal element coupled to the temperature sensing element and to selectively change the temperature of the environment about or proximate to the device;
a layer to provide thermal insulation and impact protection disposed about the thermal energy spreader and the thermal element; and
a connector to operably couple the device, the temperature sensing element and the thermal element, the thermal element being operable by the device in accordance with the signal.

10. The device case according to claim 9, further comprising a flap by which a user interface of the device is accessible.

11. The device case according to claim 9, wherein the thermal element comprises an electrically resistive material.

12. The device case according to claim 9, wherein the thermal element comprises a thermoelectric material.

13. The device case according to claim 9, wherein the temperature sensing element is operable by the device.

14. A device case, comprising:
a thermal energy spreader disposed about or proximate to a component of a device;
a temperature sensing element to sense a temperature of an environment about or proximate to the device and to issue a signal reflective thereof;
a thermal element coupled to the temperature sensing element and disposed to selectively change the temperature of the environment about or proximate to the device;
a layer to provide thermal insulation and impact protection disposed about the thermal energy spreader and the thermal element; and
a controller operably coupled to the temperature sensing element and the thermal element to control the thermal element in accordance with the signal.

15. The device case according to claim 14, further comprising a flap by which a user interface of the device is accessible.

16. The device case according to claim 14, wherein the thermal element comprises an electrically resistive material.

17. The device case according to claim 14, wherein the thermal element comprises a thermoelectric material.

18. The device case according to claim 14, further comprising a power source operably coupled to the controller.

19. The device case according to claim 14, wherein the controller comprises:
a control mechanism operably coupled to the thermal element;
a processing unit to control an operation of the control mechanism; and
a storage medium having executable instructions stored thereon, which, when executed, cause the processing unit to control the operation of the control mechanism.

20. The device according to claim 14, wherein the controller further controls an operation of the temperature sensing element.

21. (canceled)

22-23. (canceled)
